(19) United States
(12) Patent Application Publication
(10) Pub. No.: US 2023/0328875 A1
(43) Pub. Date: Oct. 12, 2023

(54) HIGH-FREQUENCY COMPONENT, ELECTRIC CIRCUIT ARRANGEMENT AND RADAR SYSTEM

(71) Applicant: Robert Bosch GmbH, Stuttgart (DE)

(72) Inventors: Kevin Stella, Ditzingen (DE); Christian Hollaender, Waldbronn (DE); Juergen Seiz, Welzheim (DE); Kai Schiemenz, Stuttgart (DE); Klaus Baur, Mietingen (DE); Marcel Mueller, Reutlingen (DE); Soeren Mjoernell, Markgroeningen (DE)

(21) Appl. No.: 18/182,523

(22) Filed: Mar. 13, 2023

(30) Foreign Application Priority Data
Apr. 6, 2022 (DE) 10 2022 203 407.4

(51) Int. Cl. H05K 1/02; H05K 1/11; G01S 13/88

(52) U.S. Cl. CPC H05K 1/0243; H05K 1/111; G01S 13/88; H05K 2201/10719; H05K 2201/10098

(57) ABSTRACT

An electronic component for high-frequency applications, in which an integrated circuit with a chip for processing high-frequency signals are arranged together with at least one signal coupling element or launcher for coupling and/or decoupling high-frequency signals in a common housing substrate. A land grid array (LGA) structure is provided on an outside of the housing substrate. An electrically conductive border is provided around the respective launcher on the surface of the housing substrate.

### CROSS REFERENCE

The present application claims the benefit under 35 U.S.C. § 119 of German Patent Application No. DE 10 2022 203 407.4 filed on Apr. 6, 2022, which is expressly incorporated herein by reference in its entirety.

### FIELD

The present invention relates to a high-frequency component as well as to an electric circuit and to a radar system containing such a high-frequency component.

### BACKGROUND INFORMATION

Integrated high-frequency circuits generate millimeter wave signals, such as those used for a radar system in a motor vehicle. In particular, frequencies in the range of about 76 gigahertz (GHz) to 81 GHz are used for this purpose. For generating or processing the high-frequency signals, integrated circuits are also increasingly employed. In conventional housings of such integrated circuits, the signals are transmitted on planar transmission lines on a printed circuit board (PCB). Such housings may be contacted, for example, by a ball grid array (BGA).

For example, U.S. Patent Application Publication No. US 2020/0365971 A1 describes a housing arrangement having an integrated circuit and a component for signal coupling and decoupling. A BGA structure is used to attach the housing arrangement to a printed circuit board.

### SUMMARY

The present invention is directed to a high-frequency component, as well as an electric circuit arrangement, and a radar system. Example advantageous embodiments of the present invention are disclosed herein.

According to an example embodiment of the present invention, the following is provided:

A high-frequency component having a housing substrate and a land grid array (LGA). The housing substrate comprises a chip element with an integrated circuit as well as at least one signal coupling element. The signal coupling element is coupled to the integrated circuit. Further, the signal coupling element is designed to emit and/or receive a high-frequency signal. The LGA is arranged on the surface of the housing substrate. Further, on the surface of the housing substrate, the LGA has an electrically conductive border around the at least one signal coupling element.

According to an example embodiment of the present invention, the following is furthermore provided:

An electric circuit assembly with a high-frequency component according to the present invention and a printed circuit board substrate. The printed circuit board substrate has an electrically conductive structure corresponding to the LGA of the high-frequency component. In particular, the high-frequency component is soldered onto the electrically conductive structure of the printed circuit board substrate or connected to the electrically conductive structure of the printed circuit board substrate in any other way.

According to an example embodiment of the present invention, the following is provided:

A radar system, in particular a radar system for a motor vehicle, having an electric circuit arrangement according to the present invention and an antenna system. The antenna system is in this case coupled to the electric circuitry arrangement. Further, the antenna system is designed to emit high-frequency signals from the high-frequency component of the electric circuit arrangement and/or provide received high-frequency signals at the high-frequency component.

### SUMMARY

The present invention is based on the recognition that numerous high-frequency applications are increasingly being used in components with integrated circuits as part of the ongoing development and miniaturization. Signal coupling elements, so-called launchers, can also be implemented in the component with the integrated circuit. In this case, the signal coupling and decoupling between the component with the integrated circuit and subsequent structures is of great importance for the transmission of the high-frequency signals, for example waveguides or the like.

It is therefore a feature of the present invention to take this realization into account and to provide a high-frequency component that allows for an optimized connection of high-frequency components with integrated circuits to subsequent structures for the signal transmission of high-frequency signals. For this purpose, according to an example embodiment of the present invention, it is provided to realize electrical contacts in the form of a so-called land grid array (LGA) on the high-frequency component with the integrated circuit. Such LGA structures on the one hand allow the high-frequency component with the integrated circuit to be attached very closely, that is to say, at a minimum distance, on a substrate, in particular a printed circuit board substrate or the like. In addition, the LGA structures also allow for a very flexible adjustment of the structures. Thus, for example, the signal coupling and decoupling on the signal coupling elements/launchers can be optimized. In addition, further flexible and adapted structures are also possible, for example for cooling or the like.

The LGA technology used here largely corresponds to the LGA system as used for the connection of integrated circuits with a chip element. In such LGA components, which only contain an integrated chip, an approximately checkerboard-like field with contact surfaces is arranged on the bottom side. Such a component can, for example, be applied on a carrier substrate with a corresponding electrically conductive structure. A solder may be applied for this purpose, for example, by means of a matrix or the like. The component can then be applied to the substrate and soldered via a suitable process.

The high-frequency component according to an example embodiment of the present invention is based on this LGA technology and creates a high-frequency component, in which not only an integrated chip is provided in the component, but also a signal coupling element or launcher, which is provided to emit high-frequency signals from the integrated chip and/or receive external high-frequency signals and forward them to the integrated chip.

In this case, the area for the signal coupling element can be adapted in a suitable manner by an adapted LGA structure on the high-frequency component. For example, an LGA structure may be provided around the signal coupling element so as to provide full shielding. It is possible to adapt the shielding to the structures of the signal coupling element very well using LGA structures. In particular, a fully closed structure is possible around an opening of the signal coupling element. Further, by using the LGA technology, the high-frequency component can also be applied very closely on a carrier substrate, that is, the distance between the high-frequency component and the carrier substrate is very small, in particular smaller than in previously used conventional technologies.

In contrast, conventional technologies such as a pin grid array (PGA) or a ball grid array (BGA) typically require a rather rigid grid. In addition, since only individual pins or solder beads are used, no extensive or closed structures can be realized as a result. Further, the distance between the structure and the carrier substrate is also typically greater in these conventional technologies.

Thus, through the use of LGA structures according to the present invention for contacting a housing of a high-frequency component with an integrated chip and signal coupling element or launcher, it is possible to provide a significantly improved connection of the component to further components. For example, the signal coupling element can be efficiently linked to a waveguide structure, such as a substrate integrated waveguide (SIW) or the like.

According to one embodiment of the present invention, the electrically conductive border around the at least one signal coupling element comprises a closed circumferential geometry. In this way, a full, closed shielding of the interior region of the signal coupling element may be provided. For example, the electrically conductive, closed circumferential geometry around the signal coupling element may be connected to a reference potential or the like. Thus, in contrast to PGA or BGA structures, which only allow individual connection points, a significantly better shielding can be achieved.

Further, such a fully closed circumferential structure around the signal coupling element protects the area of the signal outlet against an ingress of foreign bodies or contaminations. This can also, among other things, prevent degradation of the high-frequency performance due to contamination or the like. In addition, better high-frequency performance and high-frequency adaptation is achieved by the fully closed soldering walls around the signal outlet of the signal coupling element. Reflections are reduced and radiating losses are minimized.

According to one embodiment of the present invention, the inner side of the electrically conductive border, which faces the signal coupling element, has round or oval geometry.

According to an alternative embodiment of the present invention, the inner side of the electrically conductive border has an at least an approximately rectangular geometry.

In this way, the inner side of the electrically conductive border can be adapted to the respective requirements and also to the respective structure of the signal coupling element. In particular, the electrically conductive border can thus also be adapted to the high-frequency transmission paths to be connected, such as a waveguide or the like.

According to one example embodiment of the present invention, the electrically conductive border around the signal coupling element has an electrically conductive additional structure on the inner side. By way of this additional structure, it is possible, for example, to adapt the transition from the signal coupling element to a subsequent transmission component, for example a waveguide or the like. Further, a minimization of the size can also be achieved as a result.

According to one embodiment of the present invention, the LGA on the housing substrate of the high-frequency component comprises a heat removal surface. This heat removal surface can in particular be arranged in an interior region of the LGA. In this way, thermal energy may be given off by the high-frequency component to a cooling element or the like. In particular, due to the small distance between the housing substrate and a subsequent cooling body, which is made possible by the LGA structure, a particularly efficient heat removal can take place. The heat removal surface can, for example, be soldered in planar fashion to a corresponding surface of a heat removal area, e.g. on a printed circuit board substrate or the like.

Additionally or alternatively, a heat removal surface may also be provided on a top side opposite to the LGA structure.

According to one embodiment of the electric circuit arrangement of the present invention, the printed circuit board substrate comprises a coupling interface. For example, this coupling interface may be configured to couple the signal coupling element to a waveguide or the like. By such a coupling interface, a connection to an external hollow conductor can be established, for example. For example, such coupling interface may be configured as a substrate integrated waveguide (SIW), or the like. Accordingly, a high-frequency signal may be emitted from the high-frequency component to the coupling interface and from this coupling interface be conducted to a waveguide, or vice versa from the waveguide via the coupling interface to the high-frequency component.

The described configurations and further developments of the present invention may be combined with one another as desired, where appropriate. Further configurations, further developments and implementations of the present invention also include not explicitly mentioned combinations of features of the present invention described above or in the following with respect to the embodiment examples. Those skilled in the art will in particular also add individual aspects as improvements or additions to the respective basic forms of the present invention, in view of the disclosure herein.

### BRIEF DESCRIPTION OF THE DRAWINGS

Further features and advantages of the present invention are explained in the following with reference to the figures.

FIG. 1 shows a schematic illustration of a view on a bottom side of a high-frequency component, according to one example embodiment of the present invention.

FIG. 2 shows a schematic illustration of a cross-section through an electric circuit with a high-frequency component, according to one example embodiment of the present invention.

FIG. 3 shows a schematic illustration of a view on a bottom side of a high-frequency component, according to a further embodiment of the present invention.

FIG. 4 shows a schematic illustration of a view on a bottom side of a high-frequency component, according to a further embodiment of the present invention.

FIG. 5 shows a schematic illustration of a view on a bottom side of a high-frequency component according to yet a further embodiment of the present invention.

### DETAILED DESCRIPTION OF EXAMPLE EMBODIMENTS

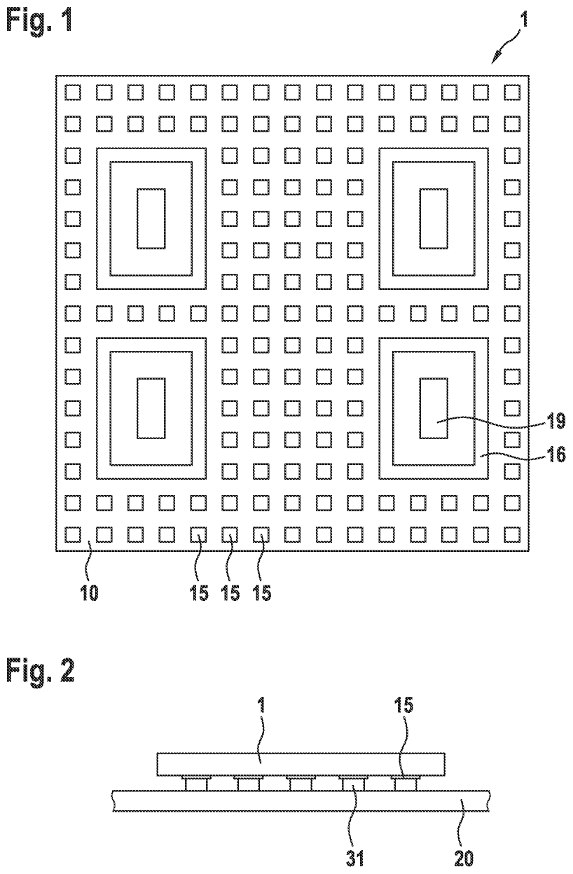

FIG. 1 shows a schematic representation of a view on a bottom side of a high-frequency component 1, according to one embodiment. Such a high-frequency component may comprise, for example, a housing substrate 10 in which a chip element with an integrated circuit is arranged. If applicable, several chip elements with integrated circuits may also be provided in the housing substrate 10. Several contact elements 15 can be provided on an outer side, preferably the bottom side of the housing substrate 10, via which the connector elements of the integrated circuit can be contacted outwardly. As shown in FIG. 1, these contact elements 15 can be in the form of a so-called land grid array (LGA). The individual contact elements 15 can have, for example, a rectangular, in particular square, shape. However, any other suitable forms, for example circles or the like, are also possible in principle. The contact elements 15 may be electrically conductive contact elements. In this way, both the power supply and signal terminals of the integrated circuit of the chip element may be contacted.

In addition, a signal coupling element 19 can be provided in the housing substrate 10. This signal coupling element 19 may be internally coupled or connected to the integrated circuit of the chip element. In this way, high-frequency signals generated by the integrated circuit of the chip element may be output or emitted via the signal coupling element 19. Additionally, or alternatively, external high-frequency signals may also be received via the signal coupling element 19 and provided to the integrated circuit of the chip element. For example, high-frequency signals may be emitted by the signal coupling element 19 into a waveguide and/or high-frequency signals may be received from a waveguide through the signal coupling element 19. Naturally, high-frequency signals may also be received from or delivered to other high-frequency conductors.

As further shown in FIG. 1, the LGA structure of the housing substrate 10 comprises an electrically conductive border 16 around the signal coupling element 19. In particular, this is a closed electrically conductive border 16 that completely encloses the signal coupling element 19 at the surface of the housing substrate 10. In principle, however, embodiments are also possible in which interruptions, for example slots or the like, are provided in the border 16.

FIG. 2 shows a schematic representation of a cross section through an electric circuit with a high-frequency component 1, according to one embodiment. The high-frequency component 1 can be the high-frequency component 1 described above, for example. In addition, high-frequency components 1 of the embodiments described in more detail below are also possible.

For example, the high-frequency component 1 may be arranged on a printed circuit board substrate 20. This printed circuit board substrate 20 may generally be any suitable printed circuit board substrate. In particular, specific printed circuit board substrates are also possible, as they are preferably used for high-frequency applications. On the printed circuit board substrate 20, an electrically conductive structure can be provided on a side facing the high-frequency component 1, which corresponds to the LGA structure of the high-frequency component 1. In this way, electrical contacting of the conductive structure on the printed circuit board substrate 20 with the connector elements 15 of the LGA structure of the high-frequency component 1 can be established. For example, a solder or a solder paste can be applied to the electrically conductive structure by means of a squeegee process. Subsequently, the high-frequency component 1 may be placed on the printed circuit board substrate 20 having the corresponding conductive structure and be soldered using a suitable soldering process. In this way, the contact elements 15 of the high-frequency component 1 are connected to the electrically conductive structure of the printed circuit board substrate 20 via corresponding soldered joints 31. The LGA structure of the high-frequency component 1 allows a relatively small distance d between the bottom side of the housing substrate and the printed circuit board substrate 20.

Likewise, the electrically conductive borders 16 around the signal coupling element 19 may also be soldered to corresponding structures on the printed circuit board substrate 20. This results in a full shielding of the interior region of the electrically conductive border 16 from the environment.

For example, an opening may be provided in the printed circuit board substrate 20 through which the high-frequency signals may be emitted by the signal coupling element 19 and/or external high-frequency signals may be conducted to and received by the signal coupling element 19. In this way, for example, a waveguide, in particular a waveguide antenna or the like, can be connected. Furthermore, any other components are of course possible to connect the signal coupling element 19 with external components for receiving or transmitting high-frequency signals. For example, other types of antennas, strip conductors, a substrate integrated waveguide (SIW) or the like may also be attached.

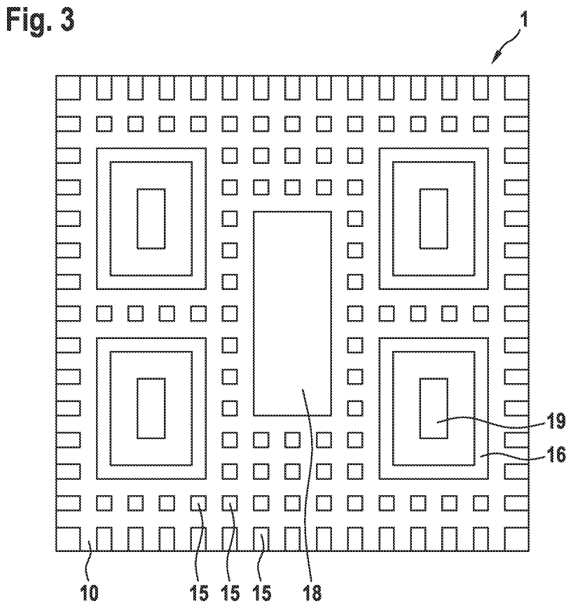

FIG. 3 shows a schematic illustration of a view of an LGA structure of a high-frequency component 1 according to another embodiment. In this respect, in principle, all explanations already made in connection with the above-described embodiments apply. The embodiment shown here differs from the above-described embodiment in particular in that a heat removal surface 18 is additionally provided on the LGA structure. This heat removal surface 18 can be a metallic surface, for example, which allows good thermal contact. In this way, thermal energy may be given off by the high-frequency component 1 to external components via the heat removal surface 18. For this purpose, the high-frequency component 1 can be arranged on the above-described printed circuit board substrate 20 such that the heat removal surface 18 is in thermal contact with a corresponding component for heat removal. For example, a structure may be provided on a printed circuit board substrate 20 on which the high-frequency component 1 is mounted, which conducts the heat from the high-frequency component 1 to the opposite side of the printed circuit board substrate 20. An active or passive cooling element may then be provided on this opposite side. For example, the structure for the transfer of heat from the heat removal surface 18 to the opposite side of the printed circuit board substrate 20 may be realized by means of through-plating elements, so-called vias. Depending on the application, it may also be sufficient to give off the heat to the surrounding area via the printed circuit board substrate 20, such that in this case the printed circuit board substrate 20 serves as the cooling element.

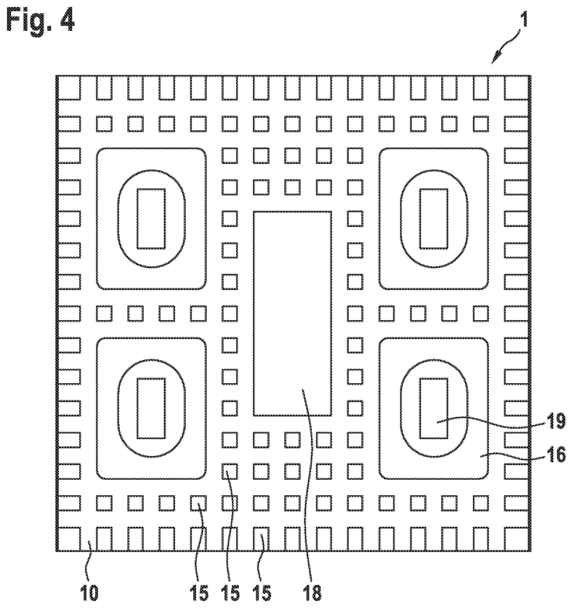

FIG. 4 shows a schematic representation of a view of an LGA structure of a high-frequency component 1 according to another embodiment. This embodiment differs from the above-described embodiments in that an inner side of the electrically conductive structure 16 has a round, rounded or optionally oval shape. Otherwise, the explanations of the above-described embodiments also apply here.

The embodiments of four signal coupling elements 19 with surrounding electrically conductive structures 16 shown in FIGS. 1, 3 and 4 serve merely as an example. It should be understood that any other number of signal coupling elements 19 are also possible in a high-frequency component 1.

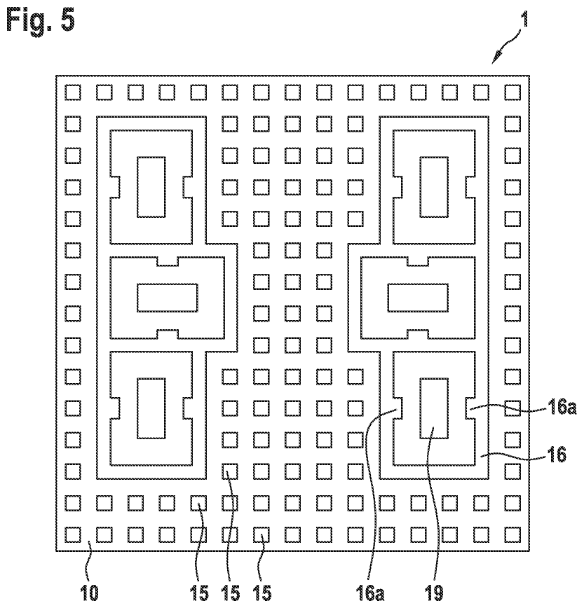

In addition to the separate, spaced-apart electrically conductive structures 16 for the individual signal coupling elements 19 in connection with the above-described embodiments, it is also possible to arrange several signal coupling elements 19 such that the electrically conductive structures 19 contact each other, or that at least partially common electrically conductive structures 16 are provided for adjacent signal coupling elements 19. This is shown by way of example in FIG. 5. Furthermore, the above explanations also apply to the embodiment shown here.

Further, as also shown in FIG. 5, an additional area 16a can be provided on the electrically conductive structures 16. This additional area 16a can be arranged particularly internally, i.e. on the side of the electrically conductive structure 16 facing the signal coupling element 19. By means of such structures, an adaptation of the high-frequency transition can be realized, for example. In this way, for example, a transition to a ridged waveguide can be realized in particular. Depending on the connection of the signal coupling element to external components, the electrically conductive structure can be adapted accordingly.

The above-described high-frequency component 1 and an electric circuit realized with it may be used for a radar system, for example. The required high-frequency signals, which are to be emitted by the radar system, can, for example, be generated by the corresponding high-frequency component 1 and output via one or multiple signal coupling elements 19. Furthermore, for example, reflected high-frequency signals received by an antenna system of the radar system may be coupled into the high-frequency component 1 via one or multiple signal coupling elements 19 and processed by the integrated circuit.

Such electric circuits for high-frequency applications, in particular for radar applications, may be used, for example, in mobile radar systems, such as for motor vehicles or the like.

In summary, the present invention relates to an electronic component for high-frequency applications, in which an integrated circuit with a chip for processing high-frequency signals are arranged together with at least one signal coupling element for coupling and/or decoupling high-frequency signals in a common housing substrate. A land grid array (LGA) structure is provided on an outside of the housing substrate. In particular, a circumferential electrically conductive border is provided on the surface of the housing substrate around the respective signal coupling element.

What is claimed is:

1. A high-frequency component, comprising:
a housing substrate including a chip element having an integrated circuit and at least one signal coupling element coupled to the integrated circuit and configured to emit and/or receive a high-frequency signal; and
a land grid array arranged on a surface of the housing substrate and having an electrically conductive border around the at least one signal coupling element on the surface of the housing substrate.

2. The high-frequency component according to claim 1, wherein the electrically conductive border around the at least one signal coupling element has a closed circumferential geometry.

3. The high-frequency component according to claim 1, wherein the electrically conductive border around the at least one signal coupling element includes multiple sections spaced apart from one another.

4. The high-frequency component according to claim 1, wherein an inner side of the electrically conductive border facing towards the signal coupling element has a round or oval geometry.

5. The high-frequency component according to claim 1, wherein an inner side of the electrically conductive border facing towards the signal coupling element has an at least approximately rectangular geometry.

6. The high-frequency component according to claim 1, wherein the electrically conductive border around the at least one signal coupling element includes an electrically conductive additional structure on an inner side facing towards the signal coupling element.

7. The high-frequency component according to claim 1, wherein the land grid array includes a heat removal surface.

8. An electric circuit arrangement, comprising:
a high-frequency component including:
a housing substrate including a chip element having an integrated circuit and at least one signal coupling element coupled to the integrated circuit and configured to emit and/or receive a high-frequency signal, and
a land grid array arranged on a surface of the housing substrate and having an electrically conductive border around the at least one signal coupling element on the surface of the housing substrate; and
a printed circuit board substrate having an electrically conductive structure corresponding to the land grid array of the high-frequency component, wherein the high-frequency component is electrically contacted with the electrically conductive structure of the printed circuit board substrate.

9. The electric circuit arrangement according to claim 8, wherein the printed circuit board substrate includes a coupling interface configured to couple the signal coupling element to a waveguide.

10. The electric circuit assembly according to claim 9, wherein the coupling interface includes a metallized opening in the printed circuit board substrate configured to couple a high-frequency signal from the signal coupling element through the metallized opening to an antenna on an opposite side of the printed circuit board.

11. A radar system for a motor vehicle, comprising:
an electric circuit arrangement, including:
a high-frequency component including:
a housing substrate including a chip element having an integrated circuit and at least one signal coupling element coupled to the integrated circuit and configured to emit and/or receive a high-frequency signal, and
a land grid array arranged on a surface of the housing substrate and having an electrically conductive border around the at least one signal coupling element on the surface of the housing substrate; and
a printed circuit board substrate having an electrically conductive structure corresponding to the land grid array of the high-frequency component, wherein the high-frequency component is electrically contacted with the electrically conductive structure of the printed circuit board substrate; and
an antenna system coupled to the electric circuit arrangement and configured to emit high-frequency signals from the high-frequency component and to provide received high-frequency signals to the high-frequency component.
